(19) United States
(12) Patent Application Publication
(10) Pub. No.: US 2002/0168591 A1
(43) Pub. Date: Nov. 14, 2002

(54) Method for reducing silicide spiking in a gate

(76) Inventor: Chiu-Te Lee, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/851,578

(22) Filed: May 10, 2001

(51) Int. Cl. G03F 7/00; G03F 7/40

(52) U.S. Cl. 430/314; 430/311; 430/313; 430/317; 430/330

(57) ABSTRACT

A first silicon oxide layer and a polysilicon layer are formed on a silicon substrate of a semiconductor wafer, followed by a rapid thermal oxidation (RTO) process to form a second silicon oxide layer on the polysilicon layer. The second silicon oxide layer is subsequently removed. A barrier layer and a silicide layer are formed on the polysilicon layer, and a lithographic process and an etching process are performed to form a gate. Finally, a thermal process is performed to allow metal ions, that diffuse from both the silicide layer and the barrier layer to the interface of the polysilicon layer and the barrier layer, to react with the oxygen atoms absorbed by the polysilicon layer during the RTO process, to form a metallic oxide layer so as to reduce silicide layer spiking.

### FIELD OF THE INVENTION

The present invention relates to a method for reducing silicide spiking in a gate, and more particularly in a gate of a metal-oxide-semiconductor (MOS) transistor of a periphery area or a memory array area.

### DESCRIPTION OF THE PRIOR ART

With the progressive development of very large scale integration (VLSI) circuits, metal oxide semiconductor (MOS) transistors now consume less power and are widely employed in high integration processes. With the progressive development of VLSI, it is important to precisely control the quality in the fabrication process of the MOS transistor.

A MOS transistor comprises a gate and two areas that have an opposite polarity to the silicon substrate. One of the areas is called a source, and the other is called a drain. However, during the formation of the gate of the MOS transistor, silicide spiking occurs. The silicide spiking results from the solubility of titanium (Ti) and aluminum (Al) in the silicon (Si), and the metal above the polysilicon layer penetrates through the interface of the metal and the silicon to reach the silicon. The prior art uses a barrier layer to prevent silicide spiking, but its effectiveness is not sufficient. Moreover, the fabrication of the barrier layer itself results in some problems.

Please refer to FIG. 1. FIG. 1 is a schematic diagram of a gate 20 according to the prior art. According to the prior art, for the fabrication of a P-type MOS transistor, an N-type implantation is performed on a silicon substrate (not shown) of a semiconductor wafer 10 to implant an N-type dopant into the silicon substrate. A thermal drive-in process functions to form an N-well 12 in the silicon substrate, and a thermal oxidation process is employed to uniformly form a silicon dioxide (SiO₂) layer 14, with a thickness of approximately 25-75 angstroms (Å), to function as a gate oxide on the semiconductor wafer 10.

A thin film deposition process, such as a low pressure chemical vapor deposition (LPCVD), is performed to form a polysilicon layer 16 on the silicon dioxide layer 14, approximately 1500-3000 angstroms (Å) thick. To reduce the resistance of the polysilicon layer 16, a dopant is introduced into the polysilicon layer 16. The MOS transistor is a P-type material, so the dopant must be P-type such as boron (B).

Then a titanium nitride (TiN) layer 18 is formed on the doped polysilicon layer 16 by a sputtering process, with the thickness of the TiN layer 18 being approximately 200-300 angstroms (Å). A silicide layer 22 is formed on the TiN layer 18 using a sputtering process. In the prior art, the silicide layer 22 is formed of titanium silicide, and the thickness of the silicide layer 22 is approximately 800-1200 angstroms (Å). The TiN layer 18 is used to prevent silicide spiking through the interface of the silicide layer 22 and the doped polysilicon layer 16.

A photoresist layer is formed on the surface of the semiconductor wafer 10, and a photolithography process is performed to define the patterns of the gate 20. After stripping the photoresist layer, a rapid thermal oxidation (RTO) process is performed for thermal annealing, the temperature of the RTO process being approximately 800-1200° C., with a duration of approximately 20-40 seconds. To complete the MOS transistor, a drain and a source are required. This process, however, is not relevant to the present invention, and so will not be discussed.

The prior art has the following three defects:

(1) The boron atoms of the doped polysilicon layer 16 diffuse along the interface of the doped polysilicon layer 16 and the TiN layer 18, thus causing poly depletion during alternative clock operations. Moreover, this leads to a gate delay.

(2) The RTO process of the final step produces a titanium oxide (TiO) within the TiN layer 18 resulting in a discontinuity in TiN and also causing a large increase in gate delay.

(3) The barrier effect of the TiN layer 18 doesn't function well, so the titanium ions continue to penetrate into the doped polysilicon layer 16 and cause silicide spiking.

### SUMMARY OF THE INVENTION

It is therefore an objective of the present invention to solve the problem of boron diffusion.

It is another objective of the present invention to solve the problem of the discontinuity of TiN.

It is yet another objective of the present invention to solve the problem of the barrier effect of TiN.

In a preferred embodiment, a first silicon oxide layer and a polysilicon layer are formed respectively on a silicon substrate of a semiconductor wafer. A rapid thermal oxidation (RTO) process is performed to form a second silicon oxide layer on the polysilicon layer, and the second silicon oxide layer is then removed. A barrier layer and a silicide layer are formed on the polysilicon layer, and a lithographic process and etching process are performed to forma gate. Finally, a thermal process allows metal ions that diffuse from both the silicide layer and the barrier layer to the interface of the polysilicon layer and the barrier layer to react with the oxygen atoms absorbed by the polysilicon layer during the RTO process to form a metallic oxide layer so as to reduce silicide layer spiking.

The present invention uses the titanium ions of the TiN layer to react with the oxygen atoms absorbed by the polysilicon layer during the RTO process to form a metallic oxide layer formed of TiO so as to reduce silicide layer spiking. Moreover, in the present invention, the TiO of the metallic oxide layer also reacts with the silicon atoms of the polysilicon layer to form TiSiₓO_{y} to prevent the diffusion of boron atoms. Thus, the three problems of the prior art are solved.

### BRIEF DESCRIPTION OF THE DRAWINGS

FIG. 1 is a schematic diagram of a gate according to the prior art.

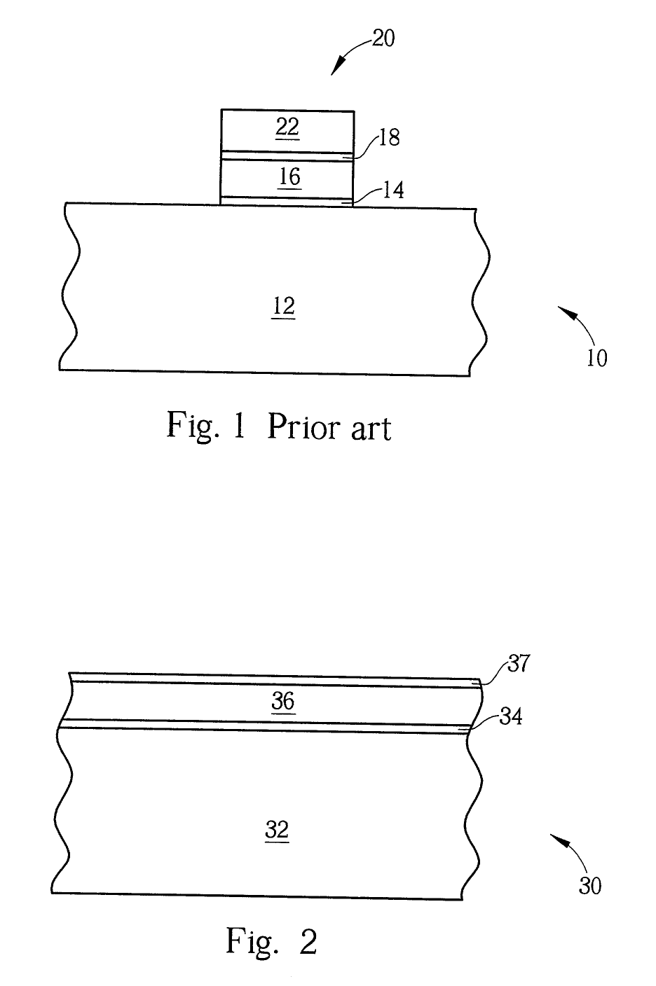

FIG. 2 to FIG. 4 are schematic diagrams of a gate of the present invention.

### DETAILED DESCRIPTION OF THE PREFERRED EMBODIMENT

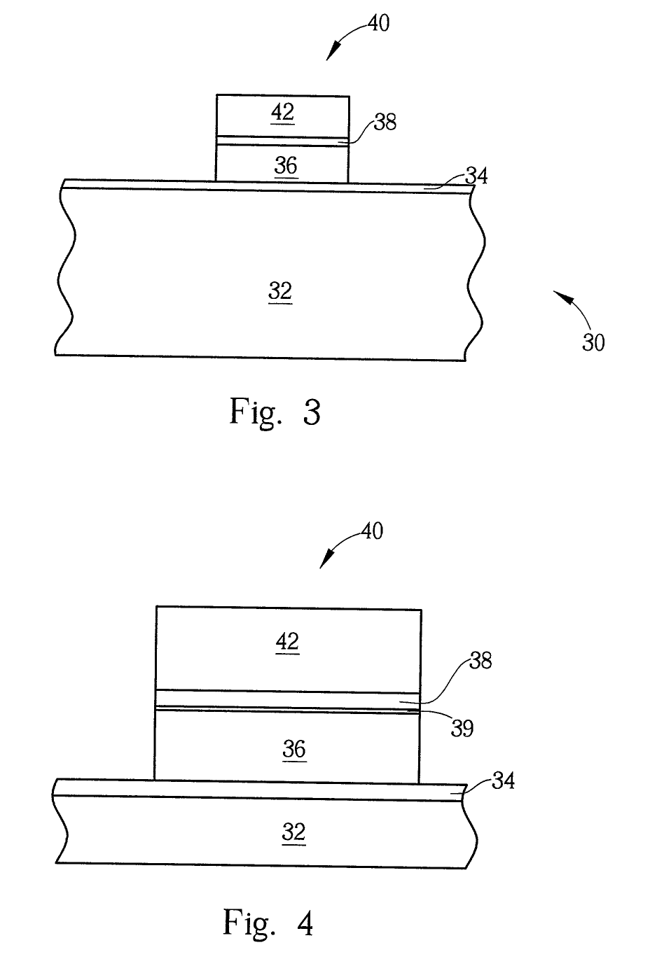

Please refer to FIG. 2 to FIG. 4. FIG. 2 to FIG. 4 are schematic diagrams of a gate 40 of the present invention. As shown in FIG. 2, using a P-type MOS transistor as an example, an N-type implantation is performed on a silicon substrate (not shown) of a semiconductor wafer 30 to implant an N-type dopant into the silicon substrate. A thermal drive-in process functions to form an N-well 32 in the silicon substrate, and a thermal oxidation process is employed to uniformly form a silicon dioxide (SiO₂) layer 34 to function as a gate oxide on the semiconductor wafer 30, approximately 25-75 angstroms (Å) thick.

A thin film deposition process, such as a low pressure chemical vapor deposition (LPCVD) process, is performed to form a polysilicon layer 36 on the first silicon oxide layer 34, with the thickness of the polysilicon layer 36 being approximately 1500-3000 angstroms (Å). To reduce the resistance of the polysilicon layer 36, a doping process is performed to introduce a dopant into the polysilicon layer 36. There are two approaches to the doping process. The first approach is that the dopant is introduced in-situ with the formation of the polysilicon layer 36. The second approach is that after the polysilicon layer 36 is formed, the dopant is implanted by a thermal diffusion process or an ion implantation process. Since the MOS transistor is P-type, the dopant must be a P-type material, such as boron (B).

A first rapid thermal oxidation (RTO) process is used to form a second silicon oxide layer 37 that is formed of silicon dioxide, or oxygen-rich oxide, with a thickness of approximately 20-30 angstroms (Å). The RTO process allows the oxygen atoms absorbed during the first RTO process to enter into the polysilicon layer 36, which means the polysilicon layer 36 absorbs some oxygen atoms during the first RTO process. The oxygen atoms absorbed by the polysilicon layer 36 don't exist in an oxide-form as the second silicon oxide layer 37. Additionally, in the second embodiment of the present invention, an ion implantation process, as previously mentioned implants the oxygen atoms into the polysilicon layer 36. Since the second silicon oxide layer 37 is not required for the present invention, a cleaning process is performed to remove the second silicon oxide layer 37. The temperature of the first RTO process is approximately 800-1200° C., with a duration of approximately 20-40 seconds. The cleaning process is performed using a cleaning solution formed of H₂O₂ and NH₄OH.

A titanium nitride (TiN) layer 38 is formed on the doped polysilicon layer 36 by a sputtering process, with the thickness of the TiN layer 38 being approximately 200-300 angstroms (Å), and then a silicide layer 42 is formed on the TiN layer 38, again by a sputtering process. The silicide layer 42 is a deposit of titanium silicide, with a thickness of approximately 800-1200 angstroms (Å). The TiN layer 38 is used to prevent silicide spiking through the interface of the silicide layer 42 and the doped polysilicon layer 36.

Then, as shown in FIG. 3, a photoresist layer (not shown) is coated on the surface of the semiconductor wafer 30, and a lithography process is performed to define the patterns of the gate 40. A dry etching process is performed along the patterns to remove portions of the silicide layer 42, the barrier layer 38, and the polysilicon layer 36 (the first silicon oxide layer 34 is preserved) to form the gate 40. The photoresist layer is then stripped. The first silicon oxide layer 34 is preserved to prevent channel effects. Additionally, the destruction of the crystal structure of the surface of the semiconductor wafer 30 caused by each ion implantation process and cleaning process is also prevented.

Finally, as shown in FIG. 4, a thermal process is performed to allow metal ions (Ti) that diffuse from both the silicide layer 42 and the barrier layer 38 to the interface of the polysilicon layer 36 and the barrier layer 38 to react with the oxygen atoms absorbed during the first RTO process to form a metallic oxide layer 39. The temperature of the rapid thermal process is approximately 900-1000° C., the duration is 25-35 seconds, and the metallic oxide 39 with a thickness of approximately 20-60 angstroms (Å) is formed of titanium oxide (TiO), so as to reduce silicide spiking in the silicide layer 42.

Additionally, to prevent the discontinuity in the TiN layer 18 during the final RTP of the prior art, as mentioned in the prior art, no oxygen reacts in all thermal processes after the second silicon oxide layer 37 is formed. After the final RTP, the TiO of the silicide layer 39 reacts with the silicon atoms of the polysilicon layer 36 to form TiSiₓO_{y,}, and so the problem of silicide spiking and diffusion of boron atoms is thereby solved. Certainly, to finish the whole MOS transistor, a drain and a source are required, however discussion of the source and the drain are not within the scope of the present invention.

The feature of the present invention is to use a thermal process to allow the metal ions (Ti), that diffuse from both the silicide layer 42 and the barrier layer 38, to the interface of the polysilicon layer 36 and the barrier layer 38 to react with the oxygen atoms absorbed during the first RTO process to form a metallic oxide layer 39. This feature prevents the occurrence of silicide spiking. Moreover, the TiO of the metallic oxide layer 39 also reacts with the silicon atoms of the polysilicon layer 36 to form TiSiₓO_{y}, so preventing the diffusion of boron and silicide spiking.

In comparison to the prior art, the method of the present invention uses both the metallic oxide layer 39, formed of Ti from the TiN of the barrier layer 38, along with oxygen absorbed by the polysilicon layer 36, and the TiSiₓO_{y} followed by the formation of the metallic oxide layer 39 to prevent the diffusion of boron and silicide spiking.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method for reducing silicide layer spiking in a gate on a semiconductor wafer, the semiconductor wafer comprising a substrate, the method comprising:
forming a first silicon oxide layer on the substrate;
forming a polysilicon layer on the first silicon oxide layer;
performing a rapid thermal oxidation (RTO) process to introduce oxygen to the surface of the polysilicon layer;
forming a barrier layer on the polysilicon layer;
forming the silicide layer on the barrier layer;
performing a lithographic process to define patterns of the gate;
performing an etching process along the patterns to remove portions of the silicide layer, the barrier layer, and the polysilicon layer so as to form the gate; and
performing a thermal process to allow metal ions that diffuse from both the silicide layer and the barrier layer to the interface of the polysilicon layer and the barrier layer to react with the oxygen atoms absorbed by the polysilicon layer during the RTO process to form a metallic oxide layer so as to reduce silicide layer spiking.

2. The method of claim 1 wherein the metallic oxide layer is formed of titanium oxide (TiO).

3. The method of claim 2 wherein the TiO also reacts with the silicon atoms of the polysilicon layer to form a TiSiₓO_{y}.

4. The method of claim 1 wherein the silicide layer is formed of titanium silicide.

5. The method of claim 1 wherein the barrier layer is formed of titanium nitride.

6. The method of claim 1 wherein the RTO process forms a second silicon oxide layer on the polysilicon layer, and the second silicon oxide layer is formed of silicon dioxide, or oxygen-rich oxide.

7. The method of claim 6 wherein the method further comprises a cleaning process after the RTO process for removing the second silicon oxide layer.

8. The method of claim 7 wherein the leaning solution comprises H₂O₂ and NH₄OH.

9. The method of claim 1 wherein portions of the first silicon oxide layer not covered by the patterns are also removed by the etching process.

10. A method for reducing silicide layer spiking in a gate on a semiconductor wafer, the semiconductor wafer comprising a substrate, the method comprising:
forming a first silicon oxide layer on the substrate;
forming a polysilicon layer on the first silicon oxide layer;
performing an oxygen implantation process on the polysilicon layer;
forming a barrier layer on the polysilicon layer;
forming the silicide layer on the barrier layer;
performing a lithographic process to define patterns of the gate;
performing an etching process along the patterns to remove portions of the silicide layer, the barrier layer, and the polysilicon layer so as to form the gate; and
performing a thermal process to allow metal ions that diffuse from both the silicide layer and the barrier layer to the interface of the polysilicon layer and the barrier layer to react with the oxygen atoms absorbed by the polysilicon layer during the RTO process to form a metallic oxide layer so as to reduce silicide layer spiking.

11. The method of claim 10 wherein the metallic oxide layer is formed of titanium oxide (TiO).

12. The method of claim 11 wherein the TiO also reacts with the silicon atoms of the polysilicon layer to form a TiSiₓO_{y}.

13. The method of claim 10 wherein the barrier layer is formed of titanium nitride.

14. The method of claim 10 wherein the silicide layer is formed of titanium silicide.

15. The method of claim 10 wherein portions of the first silicon oxide layer not covered by the patterns are also removed by the etching process.

16. A method for reducing silicide layer spiking on a semiconductor wafer, the semiconductor wafer comprising a substrate, the method comprising:
forming a polysilicon layer on the substrate;
performing a rapid thermal oxidation (RTO) process to introduce oxygen to the surface of the polysilicon layer;
forming a barrier layer on the polysilicon layer;
forming the silicide layer on the barrier layer; and
performing a thermal process to allow metal ions that diffuse from both the silicide layer and the barrier layer to the interface of the polysilicon layer and the barrier layer to react with the oxygen atoms absorbed by the polysilicon layer during the RTO process to form a metallic oxide layer so as to reduce silicide layer spiking.

17. The method of claim 16 wherein the metallic oxide layer is formed of titanium oxide (TiO).

18. The method of claim 17 wherein the TiO also reacts with the silicon atoms of the polysilicon layer to form a TiSiₓO_{y}.

19. The method of claim 16 wherein the silicide layer is formed of titanium silicide.
